(19) United States
(12) Patent Application Publication
(10) Pub. No.: US 2026/0117795 A1
(43) Pub. Date: Apr. 30, 2026

(54) FAN COVER AND A METHOD OF DIVERTING OUTPUT AIR USING FAN COVER

(71) Applicant: VERTIV CORPORATION, Westerville, OH (US)

(72) Inventors: Nayush Sanjay BURADKAR, Umred (IN); Rahul BHINTADE, Pune (IN); Dhiraj DANGE, Pune (IN)

(73) Assignee: VERTIV CORPORATION, Westerville, OH (US)

(21) Appl. No.: 19/367,660

(22) Filed: Oct. 23, 2025

(30) Foreign Application Priority Data
Oct. 24, 2024 (IN) 202421081198

(51) Int. Cl. F04D 29/56; F04D 19/00; F04D 25/08; H05K 7/20

(52) U.S. Cl. CPC F04D 29/563; F04D 25/08; H05K 7/20172; F04D 19/002

(57) ABSTRACT

A fan cover to divert the airflow of a fan to minimize thermal blind sports in electronic equipment. The fan cover comprises a frame with a hallow body and a base configured to securely fit on the rear surface of the fan. The fan cover further has a bell mouth extending from the base to define a fluid flow path and may have a hub located centrally within the hollow body of the frame and one or more ribs extending from the frame to the peripheral surface of the hub. A plurality of flaps are mounted on the peripheral surface of the bell mouth, wherein one or more of the flaps may each be angularly displaced to divert airflow in a desired direction within the electronic equipment.

### CROSS-REFERENCE TO RELATED APPLICATION

This application claims priority under 35 USC 119 to Indian Provisional Patent Application No. 202421081198 entitled “A FAN COVER AND A METHOD OF DIVERTING OUTPUT AIR USING FAN COVER” filed Oct. 24, 2024, the disclosure of which is hereby expressly incorporated by reference in its entirety.

### TECHNICAL FIELD

The present invention generally relates to the field of thermal management in an electronic equipment.

### BACKGROUND

Electronic equipment often relies on fans to cool various internal components, ensuring thermal management and optimal equipment performance. Typically, fans are integrated with electronic devices to regulate the temperature of different internal components. However, conventional fans used in such equipment often fail to provide uniform cooling across all components. This limitation arises because the fan blades are fixed in one direction, resulting in airflow concentrated in a single path. Consequently, certain areas within the electronic enclosure remain undercooled, creating “blind hot spots” where heat accumulates. These localized increases in temperature can degrade the performance of specific components and, over time, negatively impact the overall efficiency of the equipment.

Additionally, the rear geometry of conventional fans contributes to pressure drops, leading to airflow separation and turbulence. This phenomenon not only reduces the fan's cooling efficiency but also causes uneven air distribution, increasing the issue of blind spots. As a result, critical components situated in these areas do not receive adequate ventilation, leading to potential overheating. If not properly cooled, the excess heat can accumulate, reducing the lifespan of these internal components and posing a risk of damage or equipment failure.

Typically, conventional fans used in electronic equipment often fail to provide consistent cooling due to their fixed flap configuration, which leads to the formation of blind spot zone where heat accumulates. FIG. 12 illustrates an exploded isometric view of the electronic components (PCB) (106), conventional fan (108), casing with a top cover (102) and a bottom cover (104) can be installed in the casing (206) of prior art electronic equipment. The uneven cooling results in overheating of certain components, which negatively affects the equipment performance and can cause potential damage. Additionally, turbulence caused by pressure drops further reduces fan's cooling efficiency and worsens air distribution.

FIG. 13 illustrates the air flow dynamics in the prior art device illustrated in FIG. 12 as the output air exits the fan (108). The illustration highlights that, at the point where the output air is discharged from the fan (108), a pressure drop occurs. This reduction in pressure leads to a reverse airflow, or backflow, which subsequently induces turbulence along the air's flow path. This turbulence (112) disrupts the smooth passage of air, affecting the overall flow characteristics and creation of blind spot zone (114), a high velocity zone (116) and a low velocity zone (118), as depicted in FIG. 14. In the context of the present disclosure, the term “output air” herein refers to the volume and velocity of air that is discharged from the fan after it has been drawn in and propelled through its blades. It is typically measured in cubic feet per minute (CFM). The output air can also be termed as pulled-in air.

FIG. 14 illustrates a velocity map indicating the formation of thermal blind spot, high velocity zone and low velocity zone in the electronic equipment having the conventional fan arrangement of the prior art.

Further, the absence of mechanisms in the conventional fan (108) to guide pulled-in air to under-cooled areas may increase the risk of equipment failure. Therefore, a fan optimization system is needed to improve uniform cooling and effective heat dissipation across various components of an equipment.

### SUMMARY OF THE INVENTION

This summary is provided to introduce aspects related to an improved fan assembly that seeks to improve uniform cooling, seeks to reduce turbulence, and seeks to substantially minimize and preferably prevent overheating of critical components by addressing thermal blind spots in airflow.

In one aspect of the invention, a fan cover for a fan is provided which is configured to divert the air flow to improve uniform cooling, to substantially reduce turbulence and to substantially reduce and preferably prevent overheating of critical components in an electronic equipment. The fan cover comprises a frame defined by a hollow body with a base configured to securely fit on the rear surface of the fan and a bell mouth extending from said base to define a fluid flow path. The fan cover comprises a hub configured to be located centrally within the hollow body of said frame and a plurality of ribs extending from the base to the peripheral surface of said hub. Further, a plurality of flaps are mounted on the peripheral surface of said bell mouth, wherein each of said flap is angularly displaceable to a predefined angle to direct output air in a desired direction to prevent generation of thermal blind spots in the electronic equipment.

In an aspect, the fan cover comprises a fixture configured on at least one peripheral surface of said bell mouth, said fixture being configured with a plurality of slots at different angles.

In another aspect, an extended end section of said flap is provided which is configured to protrude at least partially through said fixture, said fixture facilitating locking of said extended end section in one of said slots to divert the output air in a desired direction.

In yet another aspect, the fan cover comprises a lever configured to be mounted on said extended end section of said flap, said lever being configured to angularly displace said flap to divert the output air in a desired direction.

In an aspect, each of said flaps is pivotally mounted to facilitate automatic actuation in a desired direction based on pressure gradient across the surfaces of said flaps due to the output air.

In another aspect, said hub is defined by a bowl-shaped body having a front surface and a rear surface with a tapered diameter along operative width, wherein tapered cross-section of said hub facilitates laminar flow of air without boundary layer separation and back flow of air.

In an aspect, said fan cover is configured to be fitted on the rear surface of the fan by means of snap fit, or screw attachment.

In yet another aspect, said base is provided with an operative surface that has at least a pair of projections to facilitate snap fit on rear surface of the fan.

In another aspect, each of said flaps is configured with an aerodynamic profile to reduce flow resistance during operation.

In yet another aspect, the fan cover includes sealing means, configured to be positioned between an operative surface of said base and the rear surface of the fan, said sealing means being configured to minimize air leakage and enhance the overall flow of air.

In an aspect, said fan cover is constructed of a polymeric material.

In one aspect of the invention, a method for diverting output air from a fan in an electronic equipment is provided. The method comprises the steps of: positioning a fan cover on the rear surface of the fan to establish a fluid connection with the rear surface of the fan; operating the fan to induce airflow through said fan cover; providing a plurality of displaceable flaps on said fan cover; and angularly displacing at least one of said flap of said fan cover to a predefined angle based on pre-determined airflow requirements for directing output air towards specific electronic components for avoiding thermal blind spots in the electronic equipment.

Other aspects and advantages of the invention will become apparent from the following description, taken in conjunction with the accompanying drawings, illustrating by way of example the principles of the invention.

### BRIEF DESCRIPTION OF THE DRAWINGS

The accompanying figures of the drawing, which are included to provide a further understanding of general aspects of the system/method, are incorporated in and constitute a part of this specification. These illustrative aspects of the system/method, and together with the detailed description, explain the principles of the system. No attempt is made to show structural details in more detail than is necessary for a fundamental understanding of the system and various ways in which it is practiced. The following figures of the drawing include:

FIGS. 1, 2, 3, 3A, 4 and 5 illustrate different views of the fan cover in accordance with an embodiment of the present disclosure;

FIG. 6 illustrates an exploded view demonstrating how the fan cover is fitted to an existing fan in the context of electronic equipment;

FIG. 7 illustrates a perspective elevational view illustrating the electronic equipment of FIG. 6 having the fan cover deployed therein;

FIG. 8 illustrates the air flow dynamics as air exits the fan cover in accordance with FIG. 6;

FIG. 9 illustrates a velocity map indicating the generation of a uniform airflow distribution zones in electronic equipment using a fan cover arrangement with the fan, according to the present disclosure;

FIG. 10 illustrates a velocity map indicating the movement of flap at a desired angle to restrict the formation thermal blind spot and formation of air diverted zone in the electronic equipment using the fan cover arrangement with the fan, according to the present disclosure;

FIG. 11 illustrates a method for redirecting air from the fan using the fan cover;

FIG. 12 illustrates an exploded isometric view of the electronic components (PCB), a conventional fan, and the housing, which includes both the top and bottom covers, as found in the prior art;

FIG. 13 illustrates the air flow dynamics as air exits the fan in accordance with the prior art device illustrated in FIG. 12; and

FIG. 14 illustrates a velocity map indicating the formation of thermal blind spot, high velocity zone and low velocity zone in the electronic equipment having the conventional fan arrangement of the prior art.

In the appended figures, similar components and/or features may have the same numerical reference label. Further, various components of the same type may be distinguished by following the reference label with a letter. If only the first numerical reference label is used in the specification, the description is applicable to any one of the similar components and/or features having the same first numerical reference label irrespective of the suffix.

### DESCRIPTION OF THE INVENTION

Illustrative embodiments are described with reference to the accompanying drawings. Wherever convenient, the same reference numbers are used throughout the drawings to refer to the same or like parts. While examples and features of disclosed principles are described herein, modifications, adaptations, and other implementations are possible without departing from the spirit and scope of the disclosed embodiments. It is intended that the following detailed description be considered as exemplary only, with the true scope and spirit being indicated by the following claims.

The present disclosure provides an improved fan assembly that seeks to improve uniform cooling, seeks to reduce turbulence, and seeks to substantially minimize and preferably prevent overheating of critical components by addressing thermal blind spots in airflow. The disclosure also incorporates auxiliary mechanism(s) for enhanced airflow control, to ensure effective heat dissipation and improved performance of electronic equipment. Embodiments, of the present disclosure, will now be described with reference to FIG. 1 to FIG. 11.

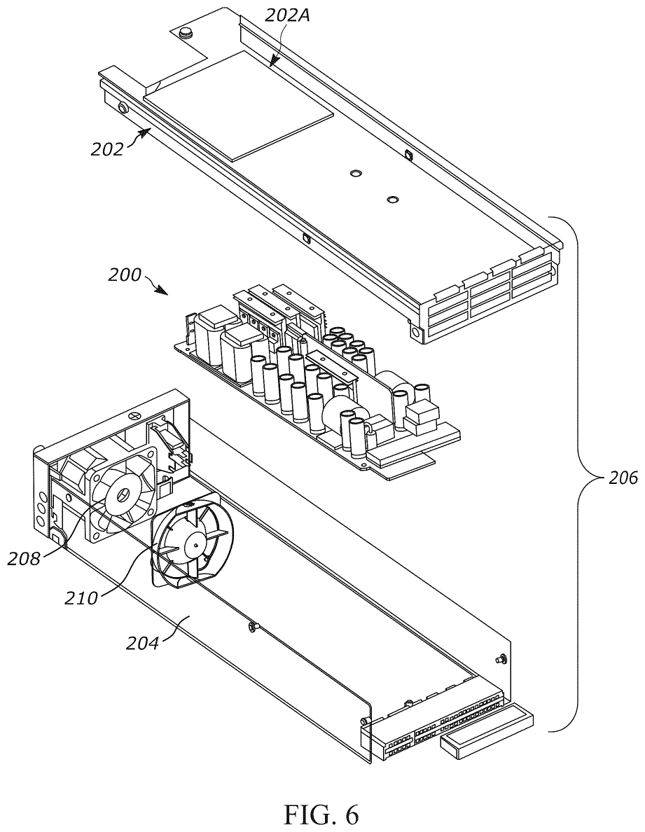

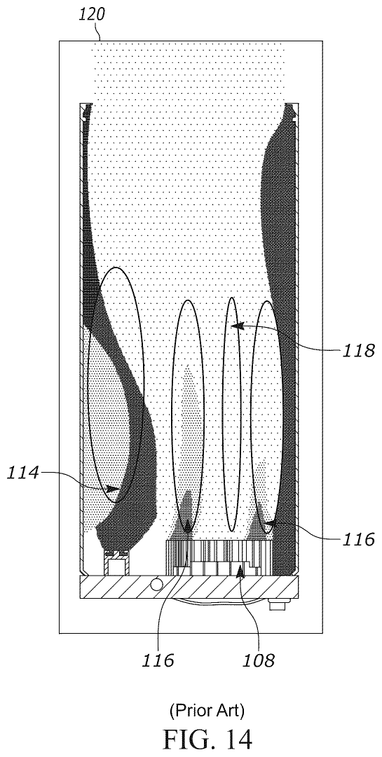

FIGS. 1-4 illustrate different views of the fan cover in accordance with the present disclosure. The present disclosure provides the fan cover (210) for the fan (208, FIG. 6). As illustrated in FIG. 6, the fan (208) typically has a front and rear surface enclosed within a casing, with the rear surface facing the electronic components (200) that require cooling. The fan cover (210) may be retrofitted onto the rear surface of the fan (208) to guide or redirect the output air or the pulled-in from the fan (208) so as to optimize the airflow distribution and prevent the formation of thermal blind spots (114, FIG. 14).

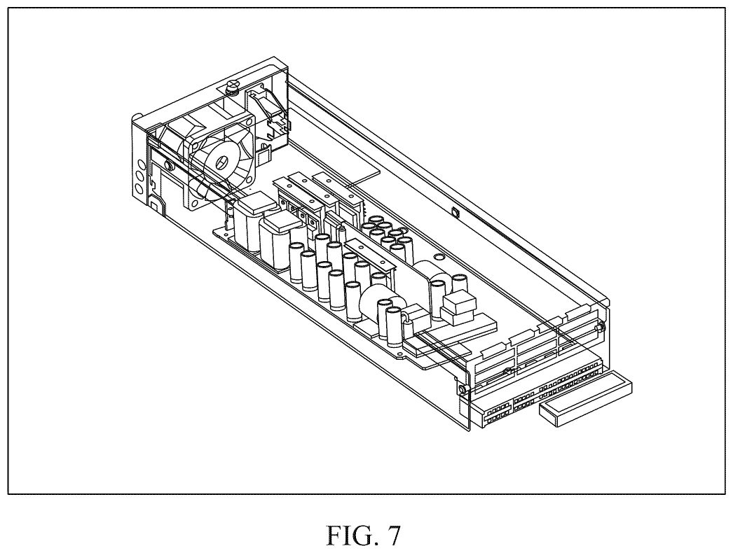

FIG. 6 illustrates an exploded view further illustrating one manner in which the fan cover is secured to an existing fan. In an implementation, the fan (208) with the fan cover (210) can be installed in the casing (206) of electronic equipment that contains multiple electronic components. The casing (206) may consist of a top cover (202) and a bottom cover (204), with the top cover (202) configured to include a cut-out portion (202A). The fan cover (210) is configured to enhance the cooling efficiency of the fan (208) by redirecting pulled-in air or the output air towards specific components within the electronic casing (206). By doing so, the components may achieve close to optimal cooling by avoiding overheating of the electronic components. In one implementation, the cut-out portion (202A) may be configured as label pasting area for the electronic equipment. In another implementation, the cut-out portion (202A) may be configured to access one or more components such as the fan cover (210) or the fan (208). FIG. 7 is a perspective elevational view illustrating the electronic equipment of FIG. 6 having the fan cover deployed therein.

Returning to FIG. 1-4, the fan cover (210) comprises a frame, defined by a hollow body with a base (212), which can be complementary to the rear surface of the fan (208). The base (212) is configured to securely fit on the fan (208). The frame further includes a bell mouth (214), extending from the operative edge of the base (212) in an operative direction. The bell mouth (214) helps to define a fluid flow path that channels the pulled-in air or the output air of the fan (208).

In an embodiment, the fan cover (210) may be mounted on the rear surface of the fan by means of snap-fit, or screw attachment. FIG. 6 illustrates one snap-fit manner in which the fan cover (210) is secured to an existing fan (208), in accordance with one embodiment of the present disclosure.

Further, as shown in FIG. 1-4, a hub (218) is centrally located within the hollow body of the frame. The hub (218) can be configured as a bowl-shaped body with a front surface 217 and a rear surface 219. In a preferred embodiment, the hub (218) may have a tapered diameter along its width. In other words, the diameter of the hub 218 at rear surface 219 is greater than the diameter of the hub 218 at the front surface 217. In embodiments, the diameter of the hub 218 incrementally decreases from the rear surface 219 to the front surface 217 The tapering shape of the hub (218) facilitates laminar or uniform airflow without boundary layer separation, backflow, or pressure drop. The tapering shape seeks to facilitate smooth and uninterrupted airflow, contributing to the improved air flow dynamics. In an embodiment, the degree of tapering can be adjusted depending on the specific application, ranging between defined limits to optimize airflow dynamics.

In another embodiment, the bell mouth (214) of the fan cover (210) may be implemented with different shapes such as conical and trapezoidal shape to achieve desired airflow distribution profiles and to extract the heat from the electronic component.

In another embodiment, as shown in FIG. 1 and FIG. 4, the hub (218) may be securely supported in the frame by at least one rib 216. In some embodiments, the hub (218) may be supported by a plurality of ribs (216A, 216B, 216C, and 216D). Each rib of the plurality of ribs (216A, 216B, 216C, and 216D) extends from the operative edge of the base (212) and connects to the peripheral surface of the hub (218). Each rib of the plurality of ribs (216 A, 216B, 216C, and 216D) provides the necessary support to keep the hub (218) centrally positioned while maintaining hollow space for air to flow. As would be understood by those skilled in the art having the present specification and claims before them, the number of ribs may vary. There may be as few as a single rib. There may be two ribs, three ribs, four ribs, so on and so forth keeping in mind the more ribs the more potential impediments to air flow.

As illustrated in FIG. 1, the fan cover (210) may be configured with a plurality of flaps (e.g., 220, 222). Each of the flaps (220, 222) may be operatively mounted on the peripheral surface of the bell mouth (214) extending towards the peripheral surface of the hub (218). The flaps (220, 222) can be angularly displaceable to a predefined angle, to allow the pulled-in air or the output air (collectively described as “airflow”) to be directed towards (or away from) specific electronic components. The movement or deflection of the flaps (220, 222) ensures that airflow can be adjusted in real-time based on cooling requirements, and thus may aid in preventing the formation of thermal blind spots (114, FIG. 14) in electronic equipment. As would be understood by those skilled in the art having the present specification and claims before them, the number of flaps may vary. There may be as few as a single flap, four flaps (as illustrated in the figures), or potentially more flaps subject to air flow and space constraints.

In an embodiment, the flaps (220, 222) may be pivotally mounted to allow for automatic actuation based on pressure gradients caused by airflow.

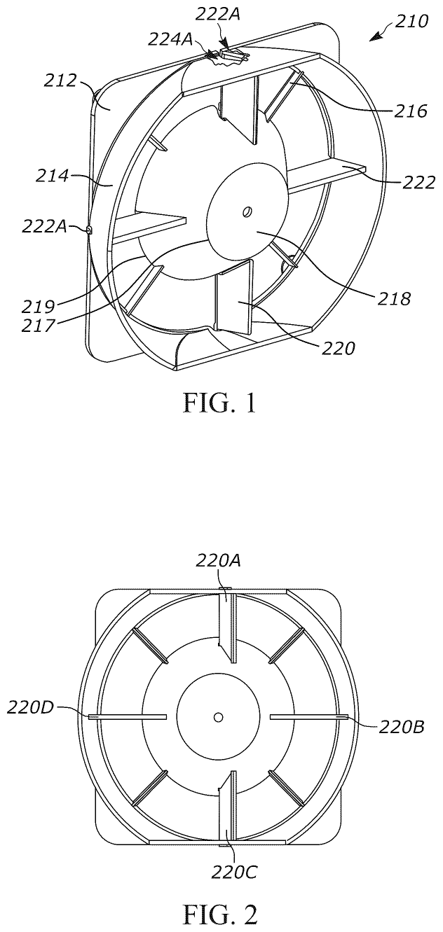

In another embodiment, illustrated in FIG. 5, the fan cover (210) may include a fixture (224) positioned on at least one peripheral surface of the bell mouth (214) to control the angular displacement of the associated flaps (e.g., 220A, FIG. 2). The fixture (224) may feature a plurality of slots (224A) at different angles, to provide a selection of pre-determined displacement angles for the associated flap. In a manual flap adjustment mode, a user may adjust and lock the respective flap into one of the plurality of slots (224A) in a desired position at a desired angle. As illustrated in FIG. 1 and FIG. 5, the extended end section (222A) associated with a respective flap may protrude at least partially through the fixture (224), and a lever on the extended end section (222A) facilitate such manual adjustment. The lever enables precise angular displacement of the associated one of the one or more flaps to selectively direct pulled-in air from or output air to a high temperature region. The slot (224A) ensures that once the desired angle of airflow is set, the respective flaps (e.g., 220A) remain in place, providing consistent airflow redirection.

In yet another embodiment, each flap (220) may have an aerodynamic profile, configured to reduce airflow resistance during operation. The aerodynamic profile helps in minimizing drag and assists in operating the fan at maximum efficiency without creating unnecessary turbulence. By enhancing the airflow dynamics, the fan cover (210) effectively improves the cooling performance of the fan.

In an embodiment, the fan cover (210) may also include sealing means, positioned between the base (212) and the rear surface of the fan. The sealing means are configured to reduce air leakage, so that the airflow is concentrated through the designated path created by the bell mouth (214) and the one or more flaps (220, 222). The sealing means may increase the overall cooling efficiency by preventing air from escaping through unintended pathways or gaps.

In another embodiment, to ensure compatibility with various environmental conditions and manufacturing processes, the fan cover (210) can be constructed from polymeric material or other suitable materials that offer durability and heat resistance. These materials ensure that the fan cover (210) can withstand prolonged use in high-temperature environments commonly found in electronic equipment.

In an embodiment, the fan cover (210) may be configured to fit different fan sizes and configurations, to allow broad applicability across various electronic devices. The snap-fit or screw-fit mechanisms can be adjusted to accommodate different fan diameters, for easier retrofitting without requiring significant modifications either to the existing fan or to the electronic components. In one embodiment, the base (212) of the fan cover (210) may include projections (212A and 212B) which facilitate attachment of the fan cover to the fan via snap-fit installation, for quickly and securely attaching the fan to the electronic equipment.

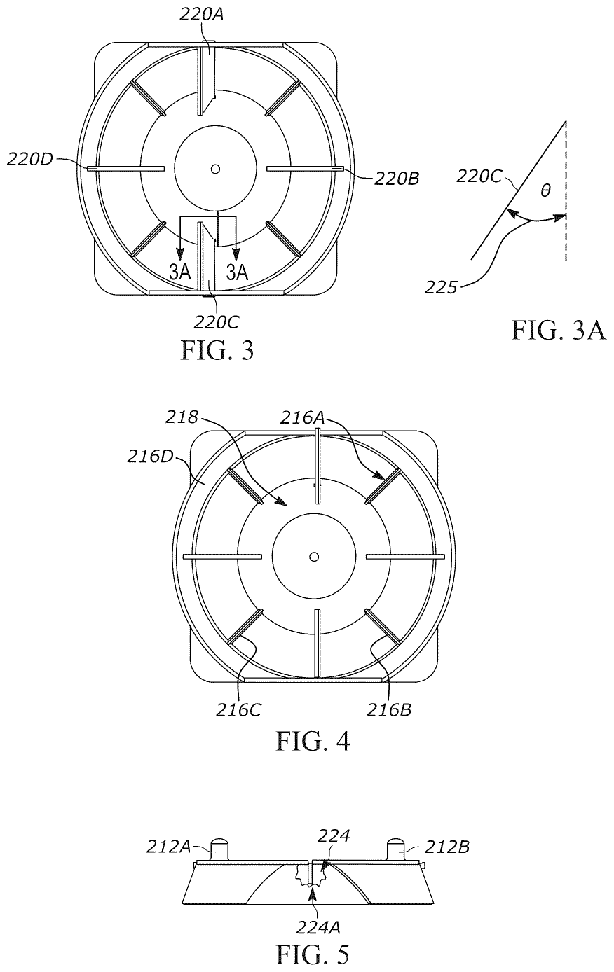

In another embodiment, shown in FIGS. 2-3, the flaps (220A, 220B, 220C and 220D) may be configured for automatic actuation, responding to airflow conditions in real-time. The flaps (220A, 220B, 220C and 220D) are positioned at the twelve o'clock, three o'clock, six o'clock, and nine o'clock positions respectively, as shown in FIGS. 2-3. When a higher pressure builds up on one side of the flap (220A, 220B, 220C and 220D), the flaps may pivot to redirect the airflow to under cooled areas. In FIG. 2, the flaps (220A and 220C) are pivoted away from flap (220D) and towards the flap (220B). Similarly, the flaps (220A and 220C) are pivoted away from the flap (220B) and towards the flap (220D) at an angle (225) as shown in FIG. 3. The direction in which the flaps pivot, and the magnitude of the angle (225, FIG. 3A) at which the flaps pivot (depicted as theta in FIG. 3A), is determined based at least on the temperature of various zones within the bell mouth (214). Even though FIG. show the angle 225 is displaced to the left of the center point, it should be understood by those of ordinary skill in the art having the present disclosure and claims before them that the flaps may be pivoted/displaced in either direction at any angle theta. This automatic adjustment ensures that the fan cover can self-regulate airflow distribution without requiring manual intervention, thus substantially optimizing the cooling efficiency in real-time.

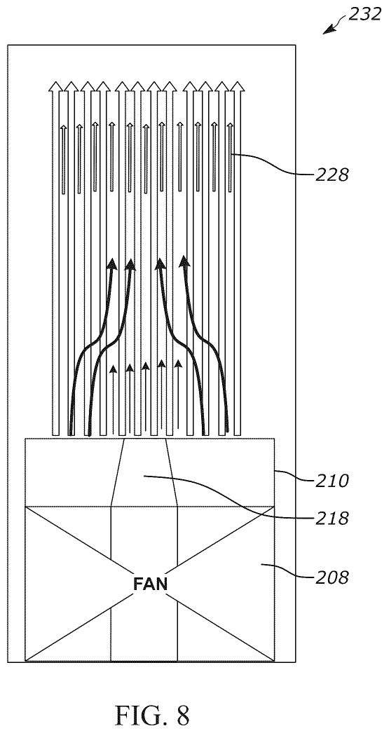

FIG. 8 illustrates the manner in which the fan cover (210) directs and controls pulled-in air or output air as it exits, substantially optimizing both the direction of airflow and speed of the airflow. The configuration of the hub (218) at the outlet facilitates smooth, laminar flow zone (228) air movement, substantially reducing turbulence and enhancing the equipment performance by efficiently managing airflow patterns. In addition, the tapered configuration of the hub (218) can be tailored for different airflow requirements.

FIG. 14 illustrates a velocity map indicating the formation of thermal blind spot, high velocity zone and low velocity zone in the electronic equipment having the conventional fan arrangement of the prior art. The velocity map visually represents the airflow distribution, with particular focus on the “thermal blind spot” areas where airflow is minimal or ineffective.

For the conventional fan (108) without the fan cover (210), the airflow velocity map (120) reveals significant regions where the air does not reach effectively, typically near the outer edges of the fan's divert area as shown in FIG. 14. These thermal blind spots (114) result from limitations in the airflow trajectory and distribution of airflow from the fan (108). Further, due to non-availability of any guiding means, there is a pressure drop at the rear surface of the fan near to the center region, which creates the formation of high velocity zone (116) as well as low velocity zone (118) and results in turbulency in the flow as shown in FIG. 14 and FIG. 13.

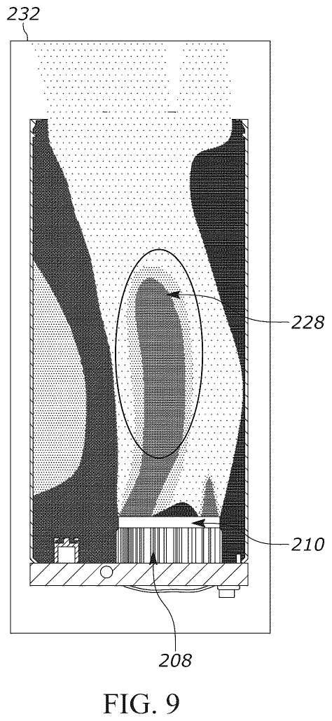

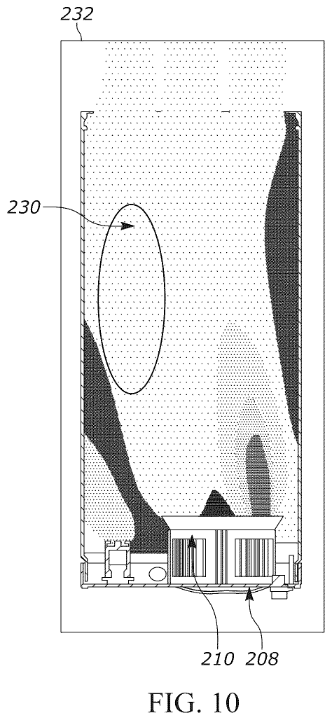

FIG. 9 illustrates a velocity map indicating the generation of a uniform airflow distribution zones in electronic equipment using a fan cover arrangement with the fan, according to the present disclosure, and FIG. 10 illustrates a velocity map indicating the movement of flap at a desired angle to restrict the formation thermal blind spot and formation of air diverted zone in the electronic equipment using the fan cover arrangement with the fan, according to the present disclosure.

The velocity map (232) for the fan with the fan cover (210) demonstrates a noticeable reduction in these thermal blind spots (114). The fan cover (210), configured to divert and optimize the airflow more efficiently, ensures more uniform airflow zone (228). The areas that were previously under-ventilated or entirely missed by the airflow from the fan without the fan cover (210) show substantial improvement with the fan cover (210) in place, reflecting an optimized air distribution pattern indicated as airflow diverted zone (230) as shown in FIG. 10.

This comparative analysis illustrates the technical advantage of using the fan cover (210) to enhance the performance of the fan by eliminating thermal blind spots (114) and achieving a more effective airflow.

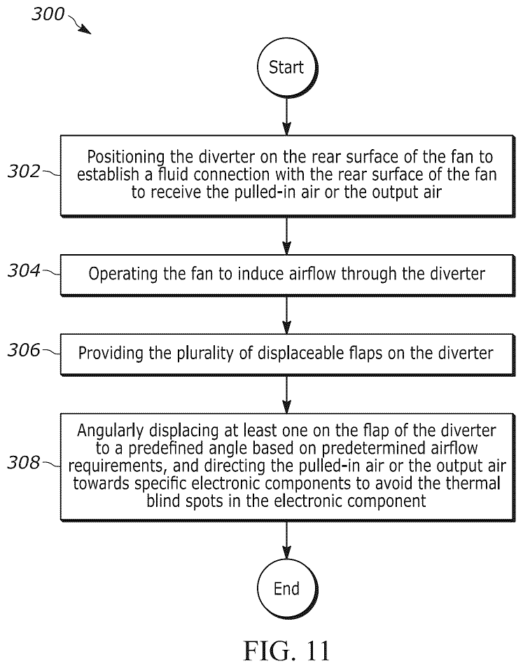

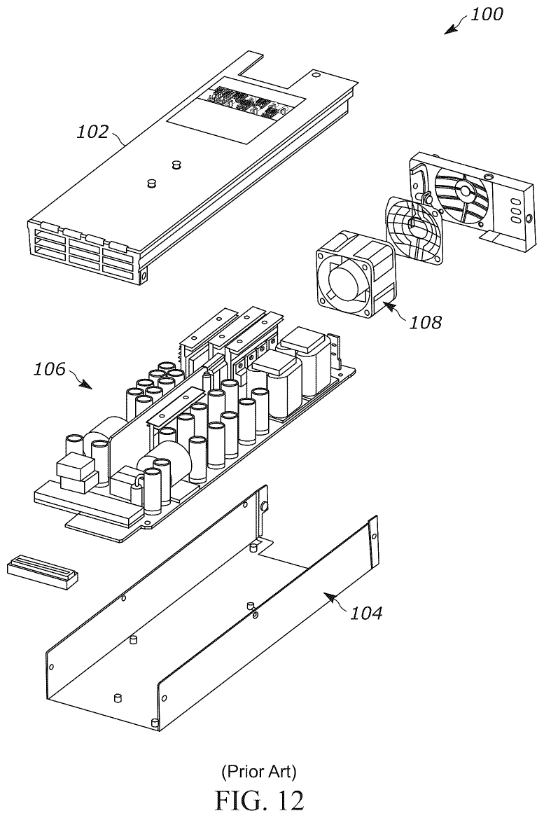

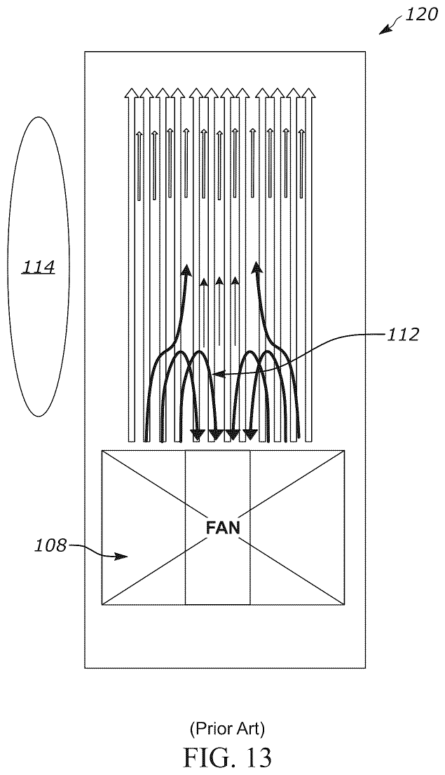

FIG. 11 illustrates a method for redirecting air from the fan using the fan cover, in accordance with the present disclosure. The method (300) may comprise the following:
In 302: positioning the fan cover (210) on the rear surface of the fan to establish a fluid connection with the rear surface of the fan (208) to receive the pulled-in air or the output air.
In 304: operating the fan (208) to induce airflow through the fan cover 5 (210).
In 306: providing the plurality of displaceable flaps (220, 222) on the fan cover (210).
And, in 308: angularly displacing at least one of the flap (220, 222) of the fan cover (210) to a predefined angle based on pre-determined airflow requirements and directing the pulled-in air or the output air towards specific electronic components to avoid the thermal blind spots in the electronic component (200).

The method may further comprise adjusting the angle of the flaps (220, 222) in real-time for optimizing the airflow dynamics to maintain more effective cooling of at least one electronic component.

The above-described features of the fan cover (210) (which may alternatively be referred to collectively as a diverter) such as the angularly adjustable flaps (220, 222) seek to improve uniform cooling of component(s) by directing the pulled-in air or the output air of the fan towards under-cooled areas, and thus may work to eliminate the thermal blind spots (114). The optimized hub (218) configuration with tapering shape ensures reduced turbulence, minimizing flow separation and improving airflow efficiency. The flap (220, 222) adjustment mechanism (both manual and/or automatic) allows real-time airflow control, to prevent the overheating of critical components and can ensure consistent equipment performance. By using adaptable fitting methods and durable materials, the fan cover (210) can be easily integrated into an existing fan, and thus enhances equipment reliability and longevity.

In an exemplary embodiment, the airflow rate is measured for both with a conventional fan without the fan cover and with the fan fitted with the fan cover (210) attachment. A series of sensors are mounted on the central hub of the fan and along the sides to monitor the airflow dynamics. For the conventional fan without the fan cover, the velocity at the center of the fan is recorded at 4.8 m/s, with a feet per minute (FPM) value of 944.9 and a cubic feet per minute (CFM) value of 31.9. At the sides of the fan, the velocity is observed at 12.7 m/s, with an FPM of 2500 and a CFM of 84.5. 5

In contrast, when the fan cover (210) attachment is used with the fan, the velocity at the center of the hub increases to 8.9 m/s, with an FPM of 1752.0 and a CFM of 59.2. At the sides, the velocity rises to 15 m/s, with an FPM of 2952.8 and a CFM of 99.8. These results or observations clearly demonstrate that the attachment of the fan cover (210) significantly enhances airflow velocity, as well as FPM and CFM, nearly doubling their values. As a result, the fan cover (210) enables more uniform airflow distribution and prevents the formation of thermal blind spots within the casing of the electronic components.

Therefore, the present disclosure not only improves the efficiency of cooling of the electronic components but also ensures better airflow management, which prolongs the lifespan of electronic components and reduces the risk of equipment or component failure.

The present disclosure described hereinabove has several technical advantages including, but not limited to, the fan cover and the method of diverting output air using fan cover, that (a) seeks to improve (if not ensure) uniform airflow distribution across all components of the electronic equipment toward substantially eliminating thermal blind spots and preventing the localized overheating of the internal components; (b) redirects pulled-in air or output air toward substantially ensuring that all components receive adequate ventilation regardless of their position within the electronic enclosure; (c) seeks to substantially minimize pressure drops and flow separation within an electronic enclosure by improving the rear surface geometry of a conventional fan, thereby reducing turbulence and enhancing the cooling efficiency; (d) seeks to mitigate uneven air distribution to better ensure that critical components located in traditionally under-cooled areas receive better, consistent cooling; (e) diverts or guides the pulled-in air or the output air of the fan toward areas prone to heat build-up, thereby improving overall equipment cooling; (f) seeks to prolong the lifespan of the electronic components and maintain equipment performance by substantially preventing overheating of the electronic equipment; (g) seeks to maintain optimal cooling across all internal components to reduce the risk of equipment failure, and increase the overall operational efficiency of the electronic equipment; and (h) may be easily integrated or retrofitted in an existing fan without significant modifications while offering compatibility with various equipment configurations.

The methods, systems, devices, graphs, and/or tables discussed herein are examples. Various embodiments may omit, substitute, or add various procedures or components as appropriate. For instance, in alternative embodiments, the methods may be performed in an order different from that described, and/or various stages may be added, omitted, and/or combined. Also, features described with respect to certain embodiments may be combined in various other embodiments. Different aspects and elements of the embodiments may be combined in a similar manner. Also, technology evolves and, thus, many of the elements are examples and do not limit the scope of the disclosure or claims. Additionally, the techniques discussed herein may provide differing results with different types of context awareness classifiers.

While illustrative and presently preferred embodiments of the disclosed systems, methods, and/or machine-readable media have been described in detail herein, it is to be understood that the inventive concepts may be otherwise variously embodied and employed, and that the appended claims are intended to be construed to include such variations, except as limited by the prior art. While the principles of the disclosure have been described above in connection with specific apparatuses and methods, it is to be clearly understood that this description is made only by way of example and not as limitation on the scope of the disclosure.

1. A fan cover for a fan, the fan generating airflow to cool at least one electronic component within an electronic equipment housing, said fan cover comprising:
a frame defined by a hollow body with a base, said base configured to securely fit on a rear surface of the fan;
a bell mouth (214) extending from an operative edge of said base in an operative direction to define a fluid flow path, said bell mouth channeling the airflow of the fan towards the at least one electronic component;
a hub operably supported by said operative edge of said base substantially centered within the hollow body of said frame; and
at least one flap operatively mounted on the peripheral surface of said bell mouth, wherein said at least one flap is configured to be angularly displaceable to least two predefined angles to direct the airflow in a desired direction to substantially minimize the generation of thermal blind spots within the electronic equipment housing.

2. The fan cover of claim 1, wherein said hub is operably supported by at least one rib extending from the operative edge of said base to peripheral surface of said hub.

3. The fan cover as claimed in claim 1, further comprising a fixture, configured on at least one peripheral surface of said bell mouth, said fixture being configured with a plurality of slots at different angles.

4. The fan cover as claimed in claim 3, wherein an extended end section of said flap is configured to protrude at least partially through said fixture, said fixture facilitating locking of said extended end section in one of said slots to divert the air flow in a desired direction.

5. The fan cover as claimed in claim 4, further comprising a lever, configured to be mounted on said extended end section of said flap, said lever being configured to angularly displace said flap to divert the air flow in a desired direction.

6. The fan cover as claimed in claim 1, wherein each of said flaps is pivotally mounted to facilitate automatic actuation in a desired direction based on pressure gradient across the surfaces of said flaps due to the air flow.

7. The fan cover as claimed in claim 1, wherein said hub is defined by a bowl-shaped body having a front surface and a rear surface with a tapered cross-section along an operative width.

8. The fan cover as claimed in claim 7, wherein the tapered cross-section of said hub facilitates laminar flow of air without boundary layer separation and back flow of air.

9. The fan cover as claimed in claim 1 further comprising a plurality of ribs, each rib of said plurality of ribs extending from the operative edge of said base to peripheral surface of said hub, said ribs configured to rigidly secure the hub within hollow body.

10. The fan cover as claimed in claim 1, wherein said fan cover is configured to be fitted on the rear surface of the fan by means of snap fit.

11. The fan cover as claimed in claim 1, wherein an operative surface of said base has at least a pair of projections to facilitate snap fit on the rear surface of the fan.

12. The fan cover as claimed in claim 1, wherein each of said flaps is configured with an aerodynamic profile to reduce flow resistance during operation.

13. The fan cover as claimed in claim 1, which includes sealing means, configured to be positioned between an operative surface of said base and the rear surface of the fan, said sealing means being configured to minimize air leakage and enhance the overall flow of air.

14. The fan cover as claimed in claim 1, said fan cover is constructed of a polymeric material.

15. A method for diverting airflow associated with a fan in an electronic equipment, comprising:
positioning a fan cover on the rear surface of the fan to establish a fluid connection with the rear surface of the fan;
operating the fan to induce airflow through said fan cover;
providing a displaceable flap on said fan cover; and
angularly displacing at least one of said flap of said fan cover to one of two or more predefined angles based on pre-determined airflow requirements for directing output air towards specific electronic components to substantially minimize thermal blind spots in the electronic equipment.

16. The method as claimed in claim 15, further comprises providing a second displaceable flap on said fan cover.

17. The method as claimed in claim 16, further comprises providing a plurality of displaceable flaps on said fan cover.

18. The method as claimed in claim 15, further comprises providing
a frame defined by a hollow body with a base, said base configured to securely fit on rear surface of the fan;
a hub operably supported by at least one rib extending from an operative edge of said base to peripheral surface of said hub, said at least one rib configured to rigidly secure the hub within said hollow body; and
channeling the airflow of the fan towards the at least one electronic component via a bell mouth extending from an operative edge of said base in an operative direction to define a fluid flow path.

19. The method as claimed in claim 15, wherein substantially minimizing further comprises substantially reducing the temperature of the components in an under cooled area.

20. The method as claimed in claim 19, wherein substantially reducing further comprises iteratively reducing the temperature of the components in the under cooled area to a lower temperature until the temperature of the components in the under cooled area is below the overheating temperature.

21. The method as claimed in claim 20, wherein iteratively reducing further comprises reducing the temperature of the components in the under cooled area to a lower temperature until the temperature of the components in the under cooled area has been changed for the better.
